(19) United States
(12) Patent Application Publication
(10) Pub. No.: US 2012/0190207 A1
(43) Pub. Date: Jul. 26, 2012

(54) PLASMA PROCESSING APPARATUS AND PLASMA PROCESSING METHOD

(75) Inventors: Eiichi NISHIMURA, Kurokawa-gun (JP); Shigeru TAHARA, Nirasaki City (JP)

(73) Assignee: TOKYO ELECTRON LIMITED, Tokyo (JP)

(21) Appl. No.: 13/357,095

(22) Filed: Jan. 24, 2012

Related U.S. Application Data
(60) Provisional application No. 61/439,192, filed on Feb. 3, 2011.

(30) Foreign Application Priority Data
Jan. 25, 2011 (JP) 2011-013381

(51) Int. Cl. H01L 21/3065

(52) U.S. Cl. 438/710; 156/345.35; 204/298.35; 257/E21.218

(57) ABSTRACT

A plasma processing apparatus performs plasma process by using a hydrogen radical generated by plasma-exciting a process gas containing hydrogen on a substrate to be processed. A high-frequency antenna includes an antenna device that is configured to resonate at a half-wavelength of high-frequency power applied from the high-frequency power source by opening two ends of the antenna device and grounding a center point of the antenna device. A barrier wall member for separating a plasma generating chamber and a plasma processing chamber includes a plurality of plate-shaped members having a plurality of openings through which the hydrogen radical passes, formed of an insulating material through which UV light does not pass, and overlapping each other at a predetermined interval, wherein the openings of one plate-shaped member are provided not to overlap the openings of another plate-shaped member.

### CROSS-REFERENCE TO RELATED PATENT APPLICATIONS

This application claims the benefits of Japanese Patent Application No. 2011-013381, filed on Jan. 25, 2011 in the Japan Patent Office, and U.S. Patent Application No. 61/439,192, filed on Feb. 3, 2011 in the U.S. Patent and Trademark Office, the disclosures of which are incorporated herein in its entirety by reference.

### BACKGROUND OF THE INVENTION

1. Field of the Invention

The present invention relates to a plasma processing apparatus and a plasma processing method.

2. Description of the Related Art

Conventionally, in a semiconductor device manufacturing field, a plasma processing apparatus using plasma is well known as an apparatus for performing, for example, film-forming process or etching process on a substrate such as a semiconductor wafer.

In a plasma processing apparatus as described above, a technology for generating plasma of a hydrogen gas and using a hydrogen radical contained in the plasma of the hydrogen gas on a substrate to be processed to perform ashing of a resist or etching of a low dielectric constant film is well known. As such, when plasma of a hydrogen gas is used, if a capacity coupled parallel plate plasma processing apparatus such as a flat plate type is used, an electrode is significantly damaged due to hydrogen plasma. Accordingly, an inductively coupled type plasma processing apparatus that generates inductively coupled plasma (ICP) is used.

A plasma processing apparatus (for example, refer to Patent Reference 1) is well known as an inductively coupled type plasma processing apparatus. In the plasma processing apparatus, a high-frequency coil having a coil spring shape is provided in a lateral wall portion of a cylindrical plasma generating chamber, and the plasma generating chamber and a processing chamber including a substrate to be processed, e.g., a semiconductor wafer to be processed, are separated by a plurality of barrier plates (barrier wall members) having through holes, and also only a radical contained in plasma is selectively used on the substrate.

As described above, in a plasma processing apparatus having a structure in which a cylindrical plasma generating chamber including a high-frequency coil provided in a lateral wall portion and a processing chamber are separated by barrier plates, since the high-frequency coil is provided in the lateral wall portion, the plasma generating chamber has a shape that is vertically long. Also, if only a radical contained in plasma generated in the vertically long plasma generating chamber is moved and used on a substrate to be processed, a moving distance of the radical is increased, and thus it is difficult to efficiently use the radical to efficiently process the substrate to be processed.

Thus, in terms of effectively performing process by a hydrogen radical, a plasma processing apparatus in which a dielectric window is provided in a ceiling portion of a processing chamber and a planar high-frequency antenna is provided in the dielectric window may be used. However, in the plasma processing apparatus having the above-described structure, there is a need to dispose the planar high-frequency antenna close to the dielectric window. Accordingly, ions contained in plasma are attracted by a voltage of the high-frequency antenna, and thus the dielectric window may be damaged, and also, a temperature of the high-frequency antenna is increased due to heat inputted from plasma, and thus a cooling mechanism for cooling the high-frequency antenna may be required.

Also, a plasma processing apparatus (for example, refer to Patent Reference 2) is well known as the above-described plasma processing apparatus in which a planar high-frequency antenna is provided in a ceiling portion of a processing chamber. In the plasma processing apparatus, two ends of a high-frequency antenna are opened, a center point or a neighboring region thereof is grounded to resonate at a half-wavelength of a high-frequency, and a substrate to be processed may be prevented from being damaged due to accelerated ions.

As described above, in a conventional technology, when a hydrogen radical is used on a substrate to be processed to perform plasma process, it is difficult to effectively use the hydrogen radical on the substrate to be processed. Also, a dielectric window is damaged due to hydrogen ions, or a high-frequency antenna is damaged due to heat inputted from plasma, and thus a cooling mechanism is required.

3. Prior Art Reference
(Patent Reference 1) Japanese Patent Laid-Open Publication No. 2009-16453
(Patent Reference 2) Japanese Patent Laid-Open Publication No. 2010-153274

### SUMMARY OF THE INVENTION

The present invention provides a plasma processing apparatus that may effectively perform plasma process by efficiently using a hydrogen radical on a substrate to be processed, may prevent a dielectric window from being damaged due to hydrogen ions, and does not require a cooling mechanism for cooling a high-frequency antenna, and a plasma processing method using the plasma processing apparatus.

According to an aspect of the present invention, a plasma processing apparatus for performing plasma process by using a hydrogen radical generated by plasma-exciting a process gas containing hydrogen on a substrate to be processed, the plasma processing apparatus including: a plasma generating chamber which generates plasma by exciting the process gas; a plasma processing chamber which is communicated with the plasma generating chamber; a holding stage which is provided in the plasma processing chamber and on which the substrate to be processed is placed; a planar high-frequency antenna which is provided outside of a plate-shaped dielectric window provided in a ceiling portion of the plasma generating chamber; a high-frequency power source which applies high-frequency power to the high-frequency antenna to generate inductively coupled type plasma in the plasma generating chamber; and a barrier wall member which separates the plasma generating chamber and the plasma processing chamber, wherein the high-frequency antenna includes an antenna device which is configured to resonate at a half-wavelength of the high-frequency power applied from the high-frequency power source by opening two ends of the antenna device and grounding a center point of the antenna device, wherein the barrier wall member includes a plurality of plate-shaped members having a plurality of openings through which the hydrogen radical passes, formed of an insulating material through which UV light does not pass, and overlapping each other at a predetermined interval, wherein the openings of one plate-shaped member are provided not to overlap the openings of another plate-shaped member.

According to another aspect of the present invention, a plasma processing method used to perform plasma process by using a hydrogen radical generated by plasma-exciting a process gas containing hydrogen on a substrate to be processed, wherein the plasma process is performed on the substrate to be processed by using a plasma processing apparatus, wherein the plasma processing apparatus includes: a plasma generating chamber which generates plasma by exciting the process gas; a plasma processing chamber which is communicated with the plasma generating chamber; a holding stage which is provided in the plasma processing chamber and on which the substrate to be processed is placed; a planar high-frequency antenna which is provided outside of a plate-shaped dielectric window provided in a ceiling portion of the plasma generating chamber; a high-frequency power source which applies high-frequency power to the high-frequency antenna to generate inductively coupled type plasma in the plasma generating chamber; and a barrier wall member which separates the plasma generating chamber and the plasma processing chamber, wherein the high-frequency antenna includes an antenna device which is configured to resonate at a half-wavelength of the high-frequency power applied from the high-frequency power source by opening two ends of the antenna device and grounding a center point of the antenna device, wherein the barrier wall member includes a plurality of plate-shaped members having a plurality of openings through which the hydrogen radical passes, formed of an insulating material through which UV light does not pass, and overlapping each other at a predetermined interval, wherein the openings of one plate-shaped member are provided not to overlap the openings of another plate-shaped member.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-sectional view of a plasma processing apparatus according to an embodiment of the present invention;

FIG. 2 is a schematic view of a high-frequency antenna of the plasma processing apparatus of FIG. 1;

FIG. 3 is a view showing a relationship between a voltage and a current in the high-frequency antenna of FIG. 2;

FIG. 4 is a schematic cross-sectional view showing main components of the plasma processing apparatus of FIG. 1;

FIG. 5 is a schematic cross-sectional view showing main components of the plasma processing apparatus of FIG. 1;

FIG. 6 is a graph showing a result obtained by measuring a sputtering amount of a dielectric window;

FIGS. 7A and 7B are graphs showing a result obtained by measuring an etching rate; and

FIGS. 8A and 8B are graphs showing a result obtained by measuring an etching rate.

### DETAILED DESCRIPTION OF THE INVENTION

Now, an exemplary embodiment according to the present invention will be described in detail with reference to the accompanying drawings.

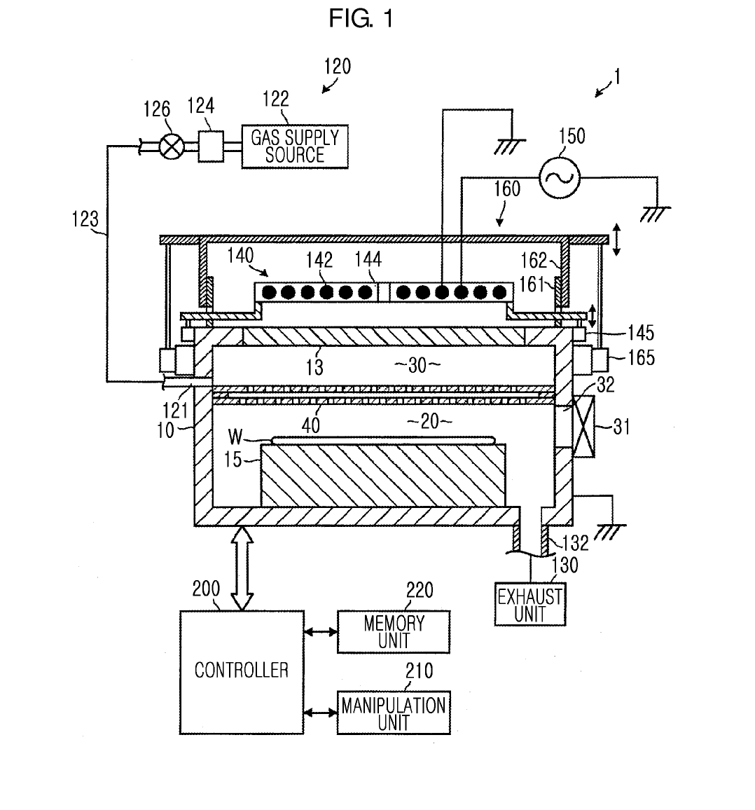

FIG. 1 is a schematic cross-sectional view of a plasma processing apparatus 1 according to an embodiment of the present invention. As shown in FIG. 1, the plasma processing apparatus 1 includes a processing chamber 10. The processing chamber 10 is formed of, for example, aluminum of which a surface is anodized and has a nearly cylindrical shape. A holding stage 15 on which a substrate to be processed, e.g., a semiconductor wafer W, is placed is provided on a bottom portion of the inside of the processing chamber 10. For example, an electrostatic chuck (not shown) for adsorbing the substrate to be processed is provided on a substrate holding surface of the holding stage 15.

A dielectric window 13 formed of a dielectric material (insulator) such as quartz or ceramic is provided to face the holding stage 15 in a ceiling portion of the processing chamber 10. The dielectric window 13 is formed in a disc shape to airtightly seal a circular opening provided in the ceiling portion of the processing chamber 10.

A barrier wall member 40 is provided inside the processing chamber 10 to separate a plasma processing chamber 20 including the holding stage 15 at a lower side and a plasma generating chamber 30 at an upper side. The barrier wall member 40 will be described later in detail.

In the plasma processing apparatus 1, a gas supply unit 120 is provided to supply a process gas including a hydrogen gas into the plasma generating chamber 30 of the processing chamber 10. A gas inlet 121 is provided in a lateral wall portion of the processing chamber 10, and a gas supply source 122 is connected to the gas inlet 121 via a gas supply pipe 123. A mass flow controller 124 for controlling a flow rate of the process gas, and an opening/closing valve 126 are interposed in the middle of the gas supply pipe 123. The process gas supplied from the gas supply source 122 is controlled at a predetermined flow rate by the mass flow controller 124 and is supplied into the plasma generating chamber 30 of the processing chamber 10 via the gas inlet 121.

In FIG. 1, for convenience of description, the gas supply unit 120 is shown as a single line. However, the gas supply unit 120 is not limited to a case of supplying a single kind of process gas, and may supply different kinds of process gases. Also, the gas supply unit 120 is not limited to a case of supplying gas from the lateral wall portion of the processing chamber 10, and gas may be supplied from the ceiling portion of the processing chamber 10. In this case, for example, a gas inlet may be provided in the center of the dielectric window 13 to supply gas.

An exhaust unit 130 for evacuating an inside of the processing chamber 10 is connected to the bottom portion of the processing chamber 10 via an exhaust pipe 132. The exhaust unit 130 may be configured as, for example, a vacuum pump and may depressurize the inside of the processing chamber 10 to a predetermined pressure. A wafer inlet/outlet 32 is provided in the lateral wall portion of the processing chamber 10, and a gate valve 31 that airtightly seals the wafer inlet/outlet 32 and is openable/closeable is provided in the wafer inlet/outlet 32.

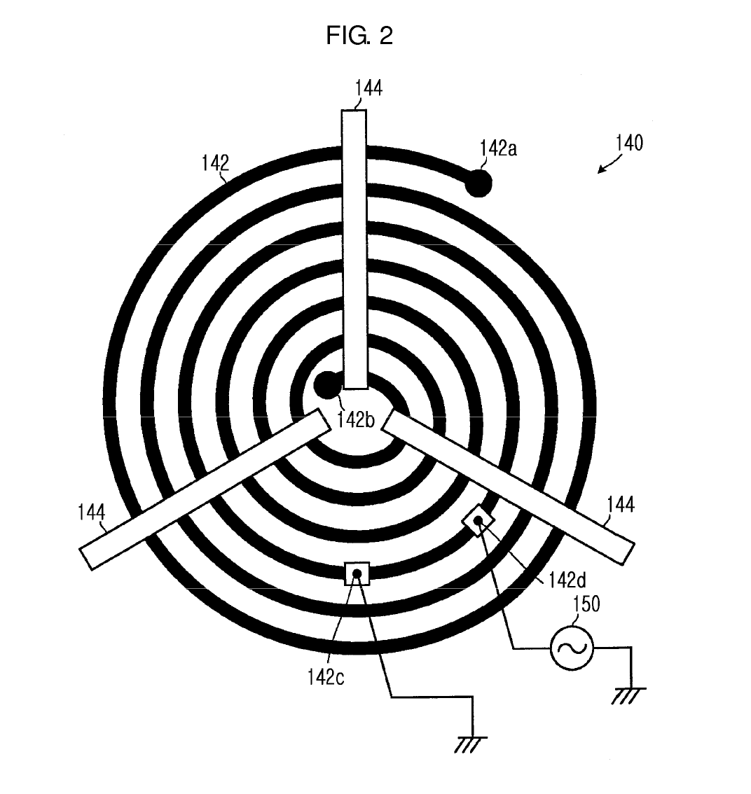

A high-frequency antenna 140 having a planar shape is provided outside of the ceiling portion of the processing chamber 10 to face an outer surface (an upper surface) of the dielectric window 13, and a shield member 160 having a nearly tubular shape (cylindrical shape in the present embodiment) is provided to cover the high-frequency antenna 140. As shown in FIG. 2, the high-frequency antenna 140 is configured to hold an antenna device 142 that has a spiral shape and is formed of a conductor, e.g., copper, aluminum, or stainless steel, by using a plurality of holding members 144. Each of the holding members 144 is formed in a bar shape, and three holding members 144 are provided to radially extend outward from around a center of the antenna device 142.

A high-frequency power source 150 is connected to the antenna device 142. The high-frequency power source 150 applies predetermined high-frequency power having a predetermined high frequency (for example, 27.12 MHz) to the antenna device 142, and thus an induced magnetic field is formed in the plasma generating chamber 30 inside the processing chamber 10. Accordingly, the process gas including the hydrogen gas introduced into the plasma generating chamber 30 is excited, thereby generating plasma. Ions contained in the plasma excited inside the plasma generating chamber 30 are blocked by the barrier wall member 40 and are stopped from entering the plasma processing chamber 20, and only a hydrogen radical contained in the plasma moves to the plasma processing chamber 20, and thus the semiconductor wafer W is processed by using the hydrogen radical.

The frequency of the high-frequency power outputted from the high-frequency power source 150 is not limited to 27.12 MHz. For example, the frequency of the high-frequency power may be 13.56 MHz, 60 MHz, or the like. However, there is a need to adjust the electric length of the antenna device 142 according to the frequency of the high-frequency power outputted from the high-frequency power source 150.

The shield member 160 includes a lower shield member 161 having a nearly cylindrical shape and fixed to the ceiling portion of the processing chamber 10, and an upper shield member 162 that is slidably provided outside of the lower shield member 161. The upper shield member 162 is formed in a nearly cylindrical shape in which an upper surface is closed and a lower surface is opened. The upper shield member 162 may slide up and down by an actuator 165 provided in the lateral wall portion of the processing chamber 10. Also, a height of the high-frequency antenna 140 may be adjusted by an actuator 145.

The plasma processing apparatus 1 includes a controller (central controller) 200, and each component of the plasma processing apparatus 1 is controlled by the controller 200. Also, in order for an operator to manage the plasma processing apparatus 1, a manipulation unit 210 including a keyboard for inputting commands or a display for displaying an operating situation of the plasma processing apparatus 1 may be connected to the controller 200.

Also, a memory unit 220 is connected to the controller 200, wherein the memory unit 220 stores a program for realizing various processes performed by the plasma processing apparatus 1 under the control of the controller 200, a recipe required to execute the program, and the like.

The memory unit 220 stores, for example, a recipe for performing necessary processes such as a process of cleaning the inside of the processing chamber 10, as well as a plurality of recipes for processing the semiconductor wafer W. The recipes may be stored in a hard disc or a semiconductor memory, or alternatively, may be stored in a storage medium such as a CD-ROM or a DVD which is set in a predetermined position of the memory unit 220

The controller 200 controls each component by invoking a desired recipe from the memory unit 220 based on a command or the like from the manipulation unit 210 so as to allow the plasma processing apparatus 1 to perform a desired process. Also, the recipes may be edited by being manipulated by the manipulation unit 210.

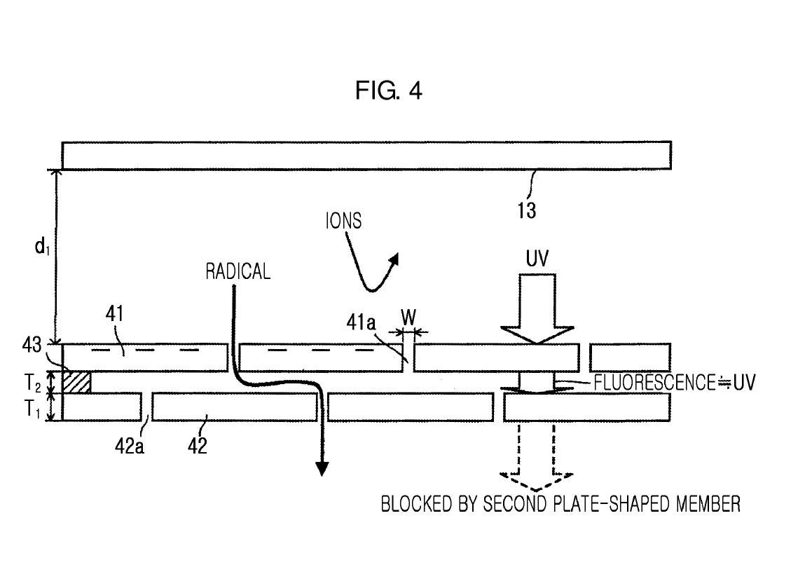

Hereinafter, the barrier wall member 40 will be described in detail. As shown in FIG. 4, in the barrier wall member 40, a plurality of plate-shaped members 41 and 42 (two plate-shaped members 41 and 42 in the present embodiment) having a plurality of slit-shaped openings 41a and a plurality of slit-shaped openings 42a, respectively, are spaced apart from each other at a predetermined interval by interposing a spacer 43 between the plate-shaped member 41 and the plate-shaped member 42, and are overlapped with each other. Also, the openings 41a of the plate-shaped member 41 are provided not to overlap the openings 42a of the plate-shaped member 42. The plate-shaped members 41 and 42 are formed of an insulating material through which ultraviolet (UV) light, in particular, UV light having a wavelength of a vacuum ultraviolet area, does not pass, e.g., quartz or ceramic (for example, alumina). Also, as shown in FIG. 4, if UV light emitted from plasma is irradiated on the plate-shaped member 41, which is adjacent to the plasma generating chamber 30 (upper side in FIG. 4), UV light is emitted as fluorescence, but the UV light emitted as fluorescence is blocked by the plate-shaped member 42, which is adjacent to the plasma processing chamber 20 (lower side in FIG. 4).

As shown in FIG. 4, the plate-shaped members 41 and 42 of the barrier wall member 40 are formed of an insulating material, and surfaces of the plate-shaped members 41 and 42 are negatively charged, and also a sheath of a positive potential is formed around the plate-shaped members 41 and 42. Accordingly, ions (e.g., hydrogen ions) contained in plasma generated inside the plasma generating chamber 30 are blocked. Then, only a hydrogen radical, which is electrically neutral, may be selectively passed through the openings 41a and 42a to be introduced into the plasma processing chamber 20. In order to improve a function of blocking ions, thicknesses T₁ (see FIG. 4) of the plate-shaped members 41 and 42 may be increased, and areas of the openings 41a and 42a may be decreased by decreasing widths W (see FIG. 4) of the openings 41a and 42a. However, if the thicknesses T₁ are excessively increased or the areas of the openings 41a and 42a are excessively decreased due to a decrease of the widths W, an amount of hydrogen radicals passing through the openings 41a and 42a is decreased.

In practice, in order to ascertain an effect of the barrier wall member 40, plasma process was performed on the semiconductor wafer W having an amorphous silicon film formed on a surface thereof. As a result, when the thicknesses T₁ of the plate-shaped members 41 and 42 are 2 mm and when the widths W of the openings 41a and 42a are 4 mm, missing parts were generated in the amorphous silicon film. Also, the same plasma process was performed when the thicknesses T₁ of the plate-shaped members 41 and 42 are 5 mm and when the widths W of the openings 41a and 42a are 2 mm. As a result, no missing parts were generated in the amorphous silicon film. Accordingly, it is preferable that the thicknesses T₁ of the plate-shaped members 41 and 42 be in a range of about 3 to about 10 mm and the widths W of the openings 41a and 42a be in a range of about 1 to about 3 mm. In the present embodiment, the thicknesses T₁ of the plate-shaped members 41 and 42 are 5 mm, and the widths W of the openings 41a and 42a are 2 mm. It is preferable that a thickness T₂ (see FIG. 4) of the spacer 43, that is, an interval between the plate-shaped member 41 and the plate-shaped member 42, be in a range of about 3 to about 10 mm. In the present embodiment, the thickness T₂ is 5 mm.

Also, in order to reliably trap ions by using the barrier wall member 40, there is a need to generate plasma in a space inside the plasma generating chamber 30 between the dielectric window 13 and the barrier wall member 40. Accordingly, there is a need to partly increase a distance between a surface of the dielectric window 13 adjacent to the plasma generating chamber 30 and a surface of the barrier wall member 40 (plate-shaped member 41) adjacent to the plasma generating chamber 30, that is, a distance d₁ (see FIG. 4). Meanwhile, if the distance d₁ is excessively increased, a distance between the plasma and the semiconductor wafer W is increased, and thus it is difficult to effectively use the hydrogen radical on the semiconductor wafer W. Thus, the distance d₁ between the surface of the dielectric window 13 adjacent to the plasma generating chamber 30 and the surface of the barrier wall member 40 adjacent to the plasma generating chamber 30 may be in a range of about 50 mm to about 110 mm.

Hereinafter, the high-frequency antenna 140 will be described in detail. As shown in FIG. 2, in the high-frequency antenna 140, two ends of the antenna device 142, that is, an outer end 142a and an inner end 142b, may be free ends (electrically floating state), and a center point of a length in a winding direction or a portion around the center point (hereinafter, referred to as center point) may be a ground 142c, thereby forming a standing wave having a half-wavelength.

In other words, a length, a diameter of a coil, a coil pitch, and a number of coil turns of the antenna device 142 are set based on a predetermined reference frequency (for example, 27.12 MHz) applied from the high-frequency power source 150 such that the antenna device 142 resonates at a half-wavelength of the reference frequency. For example, an electric length of the antenna device 142 is a length of the antenna device 142 at which the antenna device 142 resonates at half the reference frequency, that is, a length corresponding to half one wavelength when the reference frequency is 27.12 MHz. Also, the antenna device 142 may be formed in any of a pipe shape, a linear shape, a plate shape, or the like.

A power feeding point 142d for applying high-frequency power from the high-frequency power source 150 may be provided on an inner side or an outer side to the ground 142c. For example, the power feeding point 142d may be provided on a position where impedance is 50Ω. The power feeding point may be variable. In this case, the power feeding point may be automatically changed by, for example, a motor.

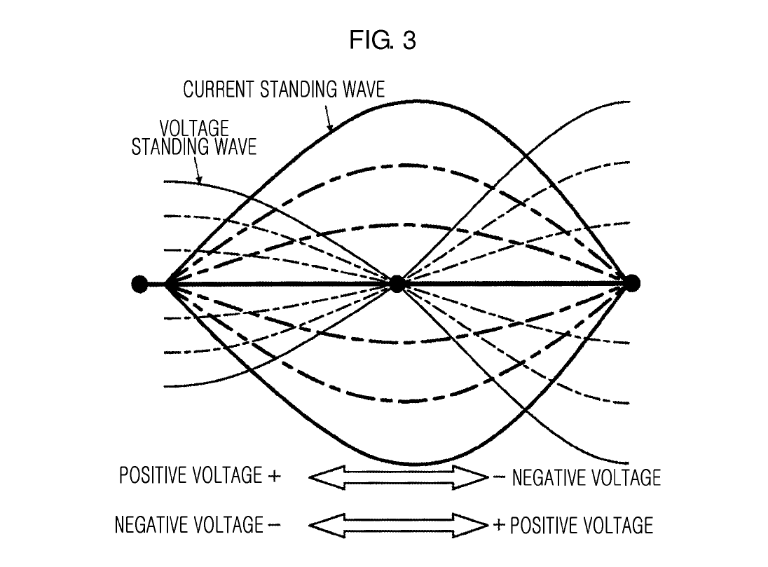

According to the antenna device 142, if the antenna device 142 resonates in a half-wavelength mode by applying high-frequency power of the reference frequency (for example, 27.12 MHz) from the high-frequency power source 150 to the high-frequency antenna 140, a voltage V applied to the antenna device 142 has a waveform at a certain moment in which the center point (ground) is 0, one end is a positive peak, and the other end is a negative peak as shown in FIG. 3. Meanwhile, a phase of a waveform of a current I applied to the antenna device 142 is different from a phase of the waveform of the voltage V by 90 degrees, and thus the current I has a waveform in which the center point (ground) is maximum and both ends are 0.

In this instance, the waveforms of the voltage V and the current I applied to the antenna device 142 are as shown in FIG. 3, in which instant capacities to positive and negative cycles of high-frequency are increased/decreased in opposite directions. In other words, the voltage V is offset due to positive and negative voltage components generated on the antenna device 142, thereby forming a standing wave of a half-wavelength mode in which an average voltage is greatly decreased. Meanwhile, regarding the current I, the center point (ground) is strongest on the antenna device 142, and a standing wave is formed due to only a positive current component or only a negative current component.

A vertical magnetic field B having a maximum strength around the center of the antenna device 142 is generated due to such a standing wave. Accordingly, a circular electric field centering around the vertical magnetic field B is excited in the plasma generating chamber 30, thereby generating plasma having a donut shape. In this instance, since an average voltage applied to the antenna device 142 is significantly small, a degree of capacity coupling is significantly low, and thus plasma having a low potential may be generated.

Here, when both the outer end 142a and the inner end 142b are grounded and the high-frequency power source 150 is connected between the outer end 142a and the ground, the voltage V and the current I have waveforms that are opposite to those shown in FIG. 3. In other words, if the antenna device 142 resonates in a half-wavelength mode by applying the high-frequency power of the reference frequency (for example, 27.12 MHz) from the high-frequency power source 150 to the high-frequency antenna 140, the voltage V applied to the antenna device 142 has the waveform at a certain moment in which the center point (ground) is maximum and the two ends are 0. Meanwhile, a phase of a waveform of the current I applied to the antenna device 142 is different from a phase of the waveform of the voltage V by 90 degrees, and thus the current I has the waveform in which the center point (ground) is 0, the one end is a positive peak, and the other end is a negative peak.

As such, if the antenna device 142 resonates in the half-wavelength mode by grounding the two ends of the antenna device 142, magnetic fields are always formed in opposite directions at an inner side of the antenna device 142 and an outer side of the antenna device 142 that are defined to the ground. Two circular electric fields are formed near an approximately-same plane by the opposite magnetic fields. In addition, since rotational directions of the two circular electric fields are always opposite to each other, the two circular electric fields interfere with each other, and thus the generated plasma may be unstable.

On the other hand, if the center point of the antenna device 142 is a ground, there is a single circular electric field to be excited as described above, and thus the circular electric field always rotates in one direction, and there is no electric field that interferes with the single circular electric field. Accordingly, when the center point of the antenna device 142 is a ground, a stable plasma may be generated compared to a case where an end of the antenna device 142 is a ground.

Also, when the two ends of the antenna device 142 are grounded, voltage components remain on the antenna device 142 in a resonant state, and thus a large amount of capacity coupled component may be generated in plasma. In this regard, when the center point of the antenna device 142 is a ground, there is a very small amount of voltage components remaining on the antenna device 142 in a resonant state as described above, and thus a capacity coupled component may hardly be generated in plasma. Accordingly, the center point of the antenna device 142 may be a ground to perform plasma process that causes small damage.

In the present embodiment, in order to resonate the antenna device 142 in the half-wavelength mode, there is a need to accurately adjust the electric length of the antenna device 142 to correspond to half the reference frequency (here, 27.12 MHz) as described above. However, it is difficult to accurately manufacture a physical length of the antenna device 142. Also, a resonance frequency of the antenna device 142 is affected by stray capacitance between the antenna device 142 and the shield member 160 as well as an unique reactance of the antenna device 142. Accordingly, even through the physical length of the antenna device 142 may be accurately manufactured, an error may occur in a distance between the antenna device 142 and the shield member 160 due to an attachment error or the like, and thus a resonance frequency may not be obtained as designed.

Therefore, in the present embodiment, a height of the shield member 160 may be adjusted so that a distance between the antenna device 142 and the shield member 160 may be adjusted, and thus stray capacitance between the antenna device 142 and the shield member 160 may vary, thereby adjusting a resonance frequency of the antenna device 142. In detail, the upper shield member 162 may be raised by driving the actuator 165, and thus the distance between the antenna device 142 and the shield member 160 may be increased. Accordingly, since stray capacitance C is decreased, the resonance frequency may be adjusted to extend an electric field of the antenna device 142.

On the contrary, if the upper shield member 162 is lowered, the distance between the high-frequency antenna 140 and the shield member 160 is decreased. Thus, since the stray capacitance C is increased, the resonance frequency may be adjusted to reduce the electric field of the antenna device 142. As such, according to the present embodiment, the stray capacitance C between the antenna device 142 and the shield member 160 may vary by adjusting the height of the shield member 160, and thus the resonance frequency of the antenna device 142 may be adjusted without changing the physical length of the antenna device 142.

Also, in the present embodiment, the height of the high-frequency antenna 140 may be adjusted, and thus a distance between the plasma and the antenna device 142 may be adjusted, thereby adjusting a plasma potential.

The above-described adjustments of the heights of the high-frequency antenna 140 and the shield member 160 may be performed by controlling the actuators 145 and 165 under the control of the controller 200. In this case, the adjustments of the heights of the high-frequency antenna 140 and the shield member 160 may be performed by an operator using the manipulation unit 210 or may be automatically controlled by the controller 200.

When the adjustment of the height of the shield member 160 is automatically performed, a high-frequency power meter (for example, reflective wave power meter) may be provided on an output side of the high-frequency power source 150, and the actuator 165 may be controlled according to high-frequency power detected by the high-frequency power meter (for example, the actuator 165 is controlled in such a way that reflective wave power is minimized) to adjust the height of the shield member 160, and thus the resonance frequency of the antenna device 142 may be automatically adjusted.

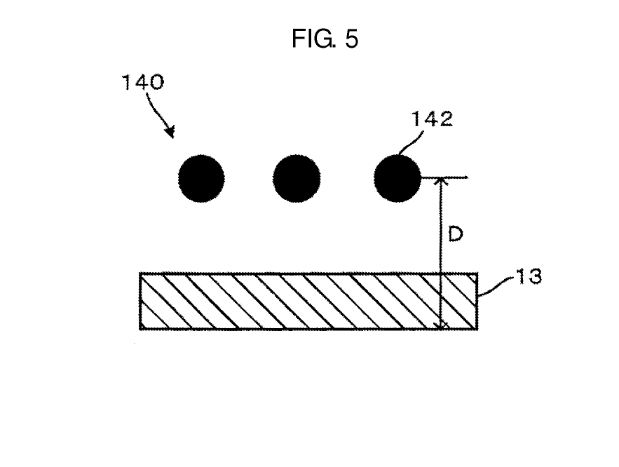

In the present embodiment, referring to FIG. 5, a distance D between the center of the antenna device 142 of the high-frequency antenna 140 and a surface of the dielectric window 13 adjacent to a vacuum side (the plasma generating chamber 30) is in a range of about 55 mm to about 90 mm. Thus, the dielectric window 13 may be prevented from being damaged by being sputtered due to, for example, accelerated hydrogen ions or the like thereon. In other words, if the distance D between the center of the antenna device 142 and the surface of the dielectric window 13 adjacent to the vacuum side is less than 55 mm, the distance between the antenna device 142 and the surface of the dielectric window 13 adjacent to the vacuum side is decreased, and thus the surface of the dielectric window 13 adjacent to the vacuum side is sputtered due to, for example, hydrogen ions or the like accelerated by an electric field of the antenna device 142, thereby significantly damaging the dielectric window 13 due to an increased sputtering amount on the dielectric window 13. Meanwhile, if the distance D between the center of the antenna device 142 and the surface of the dielectric window 13 adjacent to the vacuum side is greater than 55 mm, a degree of damage of the dielectric window 13 may be greatly reduced.

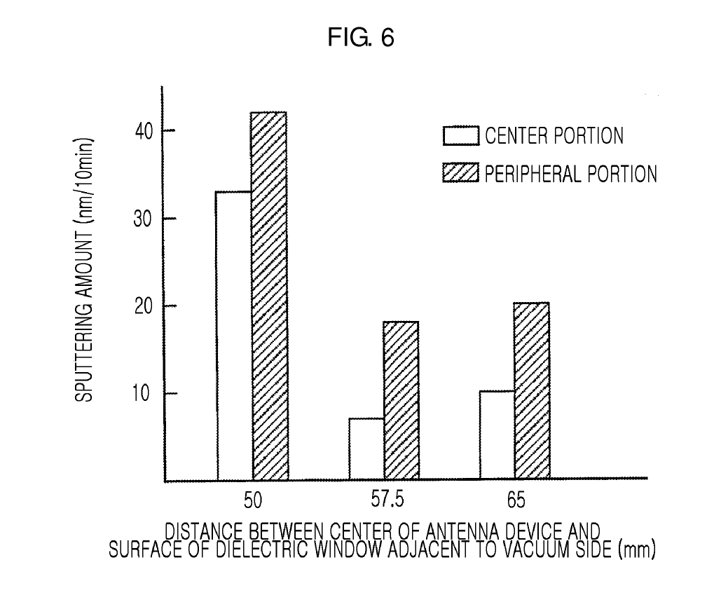

A graph of FIG. 6 shows a result obtained by measuring a sputtering amount of an ALD-SiO₂ film after 10 minutes when a semiconductor wafer on which the ALD-SiO₂ film is formed is attached to the surface of the dielectric window 13 adjacent to the vacuum side in the plasma processing apparatus 1 and when plasma of a hydrogen gas is generated in the processing chamber 10. Also, conditions of the measurement of the sputtering amount were as follows. Pressure was 5.32 Pa (40 mTorr), high-frequency power was 3000 W, a flow rate of the hydrogen gas was 500 sccm, time was 600 seconds, and a thickness of the dielectric window 13 was 30 mm. In addition, the measurement of the sputtering amount was performed on a center portion (shown as a white bar in FIG. 6) and a peripheral portion (shown as a diagonal lined-bar in FIG. 6).

As shown in FIG. 6, when the distance D between the center of the antenna device 142 and the surface of the dielectric window 13 adjacent to the vacuum side was 50 mm, the sputtering amounts were equal to or more than 30 nm on the center portion and equal to or more than 40 nm on the peripheral portion, respectively. On the other hand, when the distance D was 57.5 mm, the sputtering amounts were equal to or less than 10 nm on the center portion and 20 nm on the peripheral portion, respectively, which is equal to or less than half the sputtering amounts when the distance D was 50 mm. Also, this tendency is the same as when the distance D was 65 mm, and also approximately the same result was obtained as when the distance D was 57.5 mm. Accordingly, it is preferable that the distance D between the center of the antenna device 142 and the surface of the dielectric window 13 adjacent to the vacuum side be equal to or more than 55 mm. Also, since a difference in potential is generated between the plasma and the dielectric window 13, even though the distance D is increased, the sputtering amount may not be 0.

In addition, if the distance D exceeds 90 mm and thus the antenna device 142 is spaced apart from the dielectric window 13, plasma may be hardly generated in the processing chamber 10. Thus, it is preferable that the distance D between the center of the antenna device 142 and the surface of the dielectric window 13 adjacent to the vacuum side be equal to or less than 90 mm.

Therefore, it is preferable that the distance D between the center of the antenna device 142 and the surface of the dielectric window 13 adjacent to the vacuum side may be in the range of about 55 mm to about 90 mm. Also, in the plasma processing apparatus 1 of the present embodiment, since the dielectric window 13 and the antenna device 142 are spaced apart from each other as described above, heat inputted from plasma may hardly be transferred to the antenna device 142. Thus, there is no need to provide a cooling mechanism for cooling the antenna device 142.

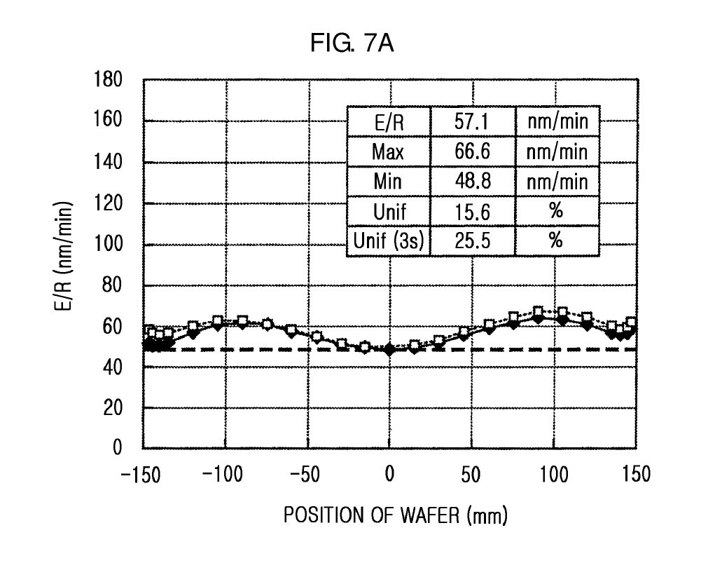

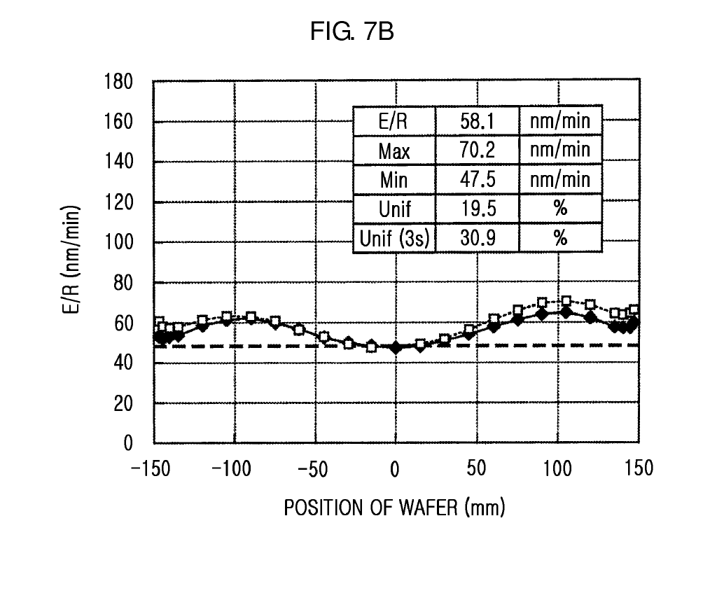

Graphs of FIGS. 7A and 7B show results obtained by measuring an etching rate of a g-line photoresist that was baked for 5 minutes when a vertical axis indicates an etching rate E/R (nm/min) and a horizontal axis indicates a distance from a center of a semiconductor wafer (that is, the horizontal axis indicates a position of the semiconductor wafer) (mm). FIG. 7A shows a case where the above-described distance D was 70 mm, and FIG. 7B shows a case where the above-described distance D was 45 mm. Also, conditions of an etching process during the measurement of the etching rate were as follows. Pressure was 200 Pa (1.5 Torr), high-frequency power was 3000 W, a flow rate of a process gas H₂/He was 100/2400 sccm, a temperature of a holding stage was 300° C., and an etching time was 180 seconds. As shown in FIGS. 7A and 7B, etching rates and a distribution of the etching rates when the above-described distance D was 70 mm were approximately the same as those when the above-described distance D was 45 mm. Accordingly, for example, even through the antenna device 142 was spaced apart from the dielectric window 13 at the distance D of 70 mm and the dielectric window 13 was prevented from being damaged, a hydrogen radical contained in plasma may be used on the semiconductor wafer W with high efficiency, and thus plasma process may be performed with high efficiency.

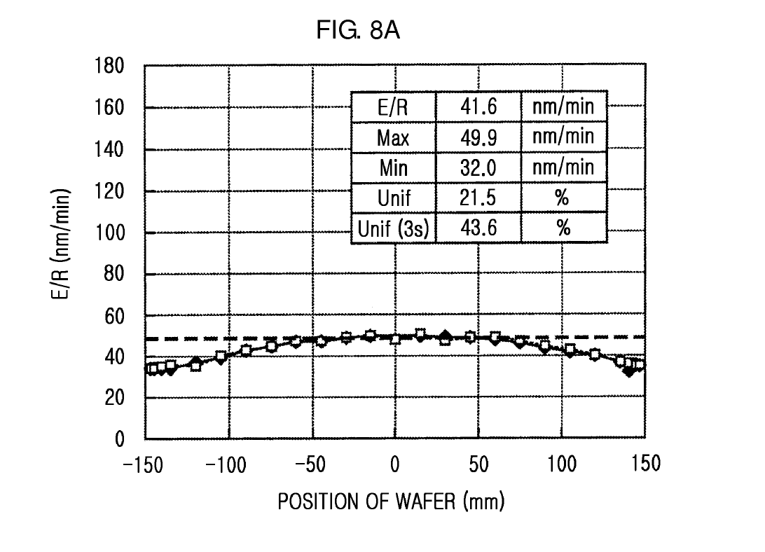

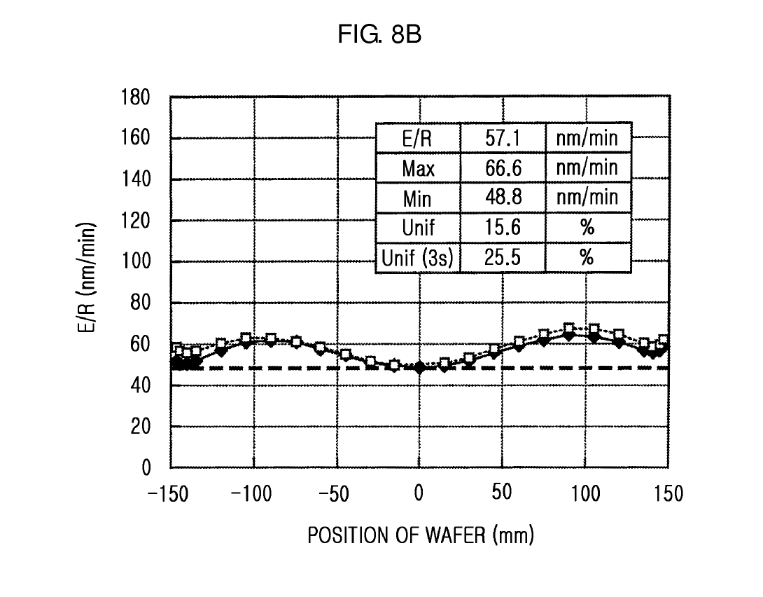

Graphs of FIGS. 8A and 8B show results obtained by measuring an etching rate of a g-line photoresist that was baked for 5 minutes when a vertical axis indicates an etching rate E/R (nm/min) and a horizontal axis indicates a distance from a center of a semiconductor wafer (that is, the horizontal axis indicates a position of the semiconductor wafer) (mm). FIG. 8A shows a case of using the plasma processing apparatus described in the Related Art of the present application and having a structure in which a cylindrical plasma generating chamber including a high-frequency coil having a coil spring shape provided in a lateral wall portion and a processing chamber are separated by a barrier wall member having the same structure as the barrier wall member 40 shown in FIG. 1. In this case, high-frequency power was 4000 W, thicknesses of two plate-shaped members of the barrier wall member were 2 mm, and a width of an opening (slit) was 4 mm. Also, FIG. 8B shows a case of using the plasma processing apparatus of the present embodiment (the thicknesses of the plate-shaped members 41 and 42 were 5 mm and the widths of the openings 41a and 42a were 2 mm), wherein high-frequency power was 3000 W.

As shown in the graphs of FIGS. 8A and 8B, in the plasma processing apparatus 1 of the present embodiment, since the barrier wall member 40 has strict conditions compared to a conventional plasma processing apparatus (that is, the plate-shaped members 41 and 42 are thick and the openings 41a and 42a are narrow), high-frequency power was low and a relatively high etching rate was obtained. As such, in the plasma processing apparatus 1 of the present embodiment, a hydrogen radical may be efficiently used on the semiconductor wafer W while preventing ions from being used, and thus plasma process may be effectively performed.

In the plasma processing apparatus 1 having the above-described configuration, when plasma process is performed on the semiconductor wafer W, the gate valve 31 is opened, the semiconductor wafer W is transferred into the plasma processing chamber 20 of the processing chamber 10 from the wafer inlet/outlet 32, the semiconductor wafer W is placed on the holding stage 15, and then is adsorbed by an electrostatic chuck.

Next, the gate valve 31 is closed, and vacuum suction is performed in the processing chamber 10 by a vacuum pump (not shown) of the exhaust unit 130 until the inside of the processing chamber 10 is a predetermined vacuum state.

Then, a process gas containing a hydrogen gas having a predetermined flow rate is supplied into the plasma generating chamber 30 of the processing chamber 10 by using the gas supply unit 120. After pressure inside the processing chamber 10 is maintained at a predetermined pressure, high-frequency power having a predetermined frequency is applied to the high-frequency antenna 140 from the high-frequency power source 150. Thus, ICP plasma of the process gas containing the hydrogen gas is generated in the plasma generating chamber 30.

Since ions in the ICP plasma have electric charges, the ions are blocked by the barrier wall member 40, and thus may rarely reach inside the plasma processing chamber 20. Meanwhile, since a hydrogen radical is electrically neutral, the hydrogen radical reaches inside the plasma processing chamber 20 via the openings 41a and 42a of the barrier wall member 40. The hydrogen radical is used on the semiconductor wafer W placed on the holding stage 15 so that plasma process, e.g., etching or ashing, may be performed on the semiconductor wafer W.

In this instance, in the plasma processing apparatus 1, ICP plasma is generated by using the planar high-frequency antenna 140, and thus plasma exists in an area that is relatively close to the semiconductor wafer W. Accordingly, an extent of the hydrogen radical moving from the plasma to the semiconductor wafer W may be low, and thus the hydrogen radical having a short lifespan may be effectively used on the semiconductor wafer W.

Also, since the barrier wall member 40 includes the plurality of plate-shaped members 41 and the plurality of plate-shaped members 42 spaced apart from one another at intervals, a low dielectric constant film or the like formed on the semiconductor wafer W may be effectively prevented from being damaged due to leakage of ions such as hydrogen ions into the plasma processing chamber 20.

In addition, by the plurality of plate-shaped members 41 and the plurality of plate-shaped members 42 of the barrier wall member 40, radiation of UV light (in particular, UV light having a wavelength of a vacuum ultraviolet area) emitted from plasma onto the semiconductor wafer W may be blocked to effectively prevent, for example, the low dielectric constant film or the like formed on the semiconductor wafer W from being damaged.

Also, as described above, since there is a very small amount of voltage components generated in the high-frequency antenna 140, hydrogen ions or the like contained in plasma may be prevented from being accelerated by an electric field, and thus the dielectric window 13 may be prevented from being damaged by being sputtered due to the accelerated hydrogen ions or the like. In the present embodiment, since the distance D (see FIG. 5) between the center of the antenna device 142 of the high-frequency antenna 140 and the surface of the dielectric window 13 adjacent to the vacuum side (the plasma generating chamber 30) is in the range of about 55 mm to about 90 mm, the dielectric window 13 may be further prevented from being damaged by being sputtered due to the accelerated hydrogen ions or the like.

Furthermore, if predetermined plasma process finishes, application of high-frequency power and supply of a process gas are stopped, and the semiconductor wafer W is transferred from of the processing chamber 10 in the order opposite to the above-described order.

According to the present invention, provided are a plasma processing apparatus that may effectively perform plasma process by efficiently using a hydrogen radical on a substrate to be processed, may prevent a dielectric window from being damaged due to hydrogen ions, and does not require a cooling mechanism for cooling a high-frequency antenna, and a plasma processing method using the plasma processing apparatus.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A plasma processing apparatus for performing plasma process by using a hydrogen radical generated by plasma-exciting a process gas containing hydrogen on a substrate to be processed, the plasma processing apparatus comprising:
a plasma generating chamber which generates plasma by exciting the process gas;
a plasma processing chamber which is communicated with the plasma generating chamber;
a holding stage which is provided in the plasma processing chamber and on which the substrate to be processed is placed;
a planar high-frequency antenna which is provided outside a plate-shaped dielectric window provided in a ceiling portion of the plasma generating chamber;
a high-frequency power source which applies high-frequency power to the high-frequency antenna to generate inductively coupled type plasma in the plasma generating chamber; and
a barrier wall member which separates the plasma generating chamber and the plasma processing chamber,
wherein the high-frequency antenna includes an antenna device which is configured to resonate at a half-wavelength of the high-frequency power applied from the high-frequency power source by opening two ends of the antenna device and grounding a center point of the antenna device,
wherein the barrier wall member includes a plurality of plate-shaped members having a plurality of openings through which the hydrogen radical passes, formed of an insulating material through which UV light does not pass, and overlapping each other at a predetermined interval, wherein the openings of one plate-shaped member are provided not to overlap the openings of another plate-shaped member.

2. The plasma processing apparatus of claim 1, wherein a distance between a center of the antenna device and a surface of the dielectric window adjacent to the plasma generating chamber is in a range of about 55 mm to about 90 mm.

3. The plasma processing apparatus of claim 1, wherein a distance between a surface of the dielectric window adjacent to the plasma generating chamber and a surface of the barrier wall member adjacent to the plasma generating chamber is in a range of about 50 mm to about 110 mm.

4. The plasma processing apparatus of claim 1, wherein the dielectric window is formed of quartz or ceramic.

5. The plasma processing apparatus of claim 1, wherein the antenna device is formed in a spiral shape.

6. The plasma processing apparatus of claim 1, wherein the openings are formed in a slit shape.

7. A plasma processing method used to perform plasma process by using a hydrogen radical generated by plasma-exciting a process gas containing hydrogen on a substrate to be processed, wherein the plasma process is performed on the substrate to be processed by using a plasma processing apparatus, wherein the plasma processing apparatus comprises:
a plasma generating chamber which generates plasma by exciting the process gas;
a plasma processing chamber which is communicated with the plasma generating chamber;
a holding stage which is provided in the plasma processing chamber and on which the substrate to be processed is placed;
a planar high-frequency antenna which is provided outside of a plate-shaped dielectric window provided in a ceiling portion of the plasma generating chamber;
a high-frequency power source which applies high-frequency power to the high-frequency antenna to generate inductively coupled type plasma in the plasma generating chamber; and
a barrier wall member which separates the plasma generating chamber and the plasma processing chamber,
wherein the high-frequency antenna includes an antenna device which is configured to resonate at a half-wavelength of the high-frequency power applied from the high-frequency power source by opening two ends of the antenna device and grounding a center point of the antenna device,
wherein the barrier wall member includes a plurality of plate-shaped members having a plurality of openings through which the hydrogen radical passes, formed of an insulating material through which UV light does not pass, and overlapping each other at a predetermined interval, wherein the openings of one plate-shaped member are provided not to overlap the openings of another plate-shaped member.

8. The plasma processing method of claim 7, wherein a distance between a center of the antenna device and a surface of the dielectric window adjacent to the plasma generating chamber is in a range of about 55 mm to about 90 mm.

9. The plasma processing method of claim 7, wherein a distance between a surface of the dielectric window adjacent to the plasma generating chamber and a surface of the barrier wall member adjacent to the plasma generating chamber is in a range of about 50 mm to about 110 mm.

10. The plasma processing method of claim 7, wherein the dielectric window is formed of quartz or ceramic.

11. The plasma processing method of claim 7, wherein the antenna device is formed in a spiral shape.

12. The plasma processing method of claim 7, wherein the openings are formed in a slit shape.
